(19) United States
(12) Patent Application Publication
(10) Pub. No.: US 2023/0041579 A1
(43) Pub. Date: Feb. 9, 2023

(54) ELECTRICAL PULSE GENERATION BY SEMICONDUCTOR OPENING SWITCH

(71) Applicant: LightCode Photonics OÜ, Tartu (EE)

(72) Inventor: Sergey Omelkov, Tartu (EE)

(21) Appl. No.: 17/878,279

(22) Filed: Aug. 1, 2022

Related U.S. Application Data
(60) Provisional application No. 63/228,915, filed on Aug. 3, 2021.

(51) Int. Cl. H01S 5/042

(52) U.S. Cl. CPC H01S 5/0428; G01S 7/484

(57) ABSTRACT

One aspect provides a method for providing a short electrical pulse using a switching circuit, the method including: providing a forward current to at least one semiconductor diode electrically connected with and controlling electrical current to an electrical component within a circuit; and switching the at least one semiconductor diode into a reverse bias by applying a reverse voltage to the at least one semiconductor diode, thereby causing the at least one semiconductor diode to enter a reverse recovery state and controlling a destination of the electrical current and generating the short electrical pulse to the destination for the duration of the reverse recovery state; the duration of the reverse recovery state being based upon a value of the forward current and a value of the reverse voltage.

### CROSS REFERENCE TO RELATED APPLICATIONS

This application claims priority to U.S. Provisional Patent Application Ser. No. 63/228,915, filed on Aug. 3, 2021, and entitled ELECTRICAL PULSE GENERATION BY SEMICONDUCTOR OPENING SWITCH , the contents of which is incorporated by referenced herein.

### BACKGROUND

One technique for determining distances or ranges between objects is using a pulsating light source that emits a light and receives a reflection of that light. The system identifies a time between the emission of the light and receipt of the reflection. From the timing information, the system is able to determine the distance of the object that created the reflection. The pulsating light source creates and receives many different light emissions and reflections, thereby allowing the system to determine many different distances between the light source and the object(s) creating the reflections. Thus, from the timing information and calculated distances, the system can accurately depict a three-dimensional image of the object(s). One common pulsating light source used in distance or range determination and image generation is LiDAR (Light Detection and Ranging). LiDAR utilizes lasers as the device light source to generate the light emissions

### BRIEF SUMMARY

In summary, one aspect provides a method for providing a short electrical pulse using a switching circuit, the method comprising: providing a forward current to at least one semiconductor diode electrically connected with and controlling electrical current to an electrical component within a circuit; and switching the at least one semiconductor diode into a reverse bias by applying a reverse voltage to the at least one semiconductor diode, thereby causing the at least one semiconductor diode to enter a reverse recovery state and controlling a destination of the electrical current and generating the short electrical pulse to the destination for the duration of the reverse recovery state; the duration of the reverse recovery state being based upon a value of the forward current and a value of the reverse voltage.

Another aspect provides a device for providing a short electrical pulse using a switching circuit, the device comprising: an electrical component receiving an electrical current; and at least one semiconductor diode electrically connected with the electrical component, wherein the at least one semiconductor diode controls electrical current to the electrical component and wherein control of the at least one semiconductor diode controls a duration of the electrical current; wherein the control of the at least one semiconductor diode comprises providing a forward current to at least one semiconductor diode electrically connected with and controlling electrical current to an electrical component within a circuit and switching the at least one semiconductor diode into a reverse bias by applying a reverse voltage to the at least one semiconductor diode, thereby causing the at least one semiconductor diode to enter a reverse recovery state and controlling a destination of the electrical current and generating the short electrical pulse to the destination for the duration of the reverse recovery state; the duration of the reverse recovery state being based upon a value of the forward current and a value of a reverse voltage applied during the reverse bias.

The foregoing is a summary and thus may contain simplifications, generalizations, and omissions of detail; consequently, those skilled in the art will appreciate that the summary is illustrative only and is not intended to be in any way limiting.

For a better understanding of the embodiments, together with other and further features and advantages thereof, reference is made to the following description, taken in conjunction with the accompanying drawings. The scope of the invention will be pointed out in the appended claims.

### BRIEF DESCRIPTION OF THE SEVERAL VIEWS OF THE DRAWINGS

FIG. 1 illustrates an example laser switching circuit with semiconductor opening switch cut-off

FIG. 2 illustrates an example laser switching circuit with semiconductor opening switch cut-on and semiconductor opening switch cut-off.

FIG. 3 illustrates an example semiconductor opening switch-based laser switching circuit for multichannel lasers.

### DETAILED DESCRIPTION

It will be readily understood that the components of the embodiments, as generally described and illustrated in the figures herein, may be arranged and designed in a wide variety of different configurations in addition to the described example embodiments. Thus, the following more detailed description of the example embodiments, as represented in the figures, is not intended to limit the scope of the embodiments, as claimed, but is merely representative of example embodiments.

Reference throughout this specification to “one embodiment” or “an embodiment” (or the like) means that a particular feature, structure, or characteristic described in connection with the embodiment is included in at least one embodiment. Thus, appearances of the phrases “in one embodiment” or “in an embodiment” or the like in various places throughout this specification are not necessarily all referring to the same embodiment.

Furthermore, the described features, structures, or characteristics may be combined in any suitable manner in one or more embodiments. In the following description, numerous specific details are provided to give a thorough understanding of claimed embodiments. One skilled in the relevant art will recognize, however, that the various described embodiments can be practiced without one or more of the specific details, or with other methods, components, materials, et cetera. In other instances, well-known structures, materials, or operations are not shown or described in detail. The following description is intended only by way of example, and simply illustrates certain example embodiments.

Pulsed light sources may be used in a variety of systems containing circuitry in order to determine information regarding the system or the environment surrounding the system. For example, pulsed light sources may be used for obtaining timing marks, photorecording, and the like. When generating the light pulses for distance or range determination or other information regarding the system or environment, it is desirable to keep the light pulses as short as possible. However, while the light pulses are short, the peak illumination power needs to be reasonably high. Accordingly, these light sources are generally built using gallium nitride (GaN) semiconductors, silicon carbide (SiC) semiconductors, or similar modern semiconductor technology. These technologies can be used within LiDAR systems and can drive LiDAR lasers with the peak power of several tens of watts. However, the shortest pulse duration achieved in these cases is barely below 1 nanosecond (ns), which may be longer than desired for many applications. Additionally, these transistors are expensive and require specific driver circuits, thereby making the entire system expensive and larger to accommodate the increased number of electronic components, especially in the case of multichannel lasers.

In traditional laser diode switching circuits, for example, those used in LiDAR or other circuits or devices requiring switching of similar currents and voltages, a current from a direct current (DC) power supply is switched into a laser diode via a semiconductor transistor. In the case of multichannel light sources, each channel has a laser diode and corresponding semiconductor transistor. The length of the light pulse is controlled by the opening duration of the transistor which is controlled by the duration of a gate pulse that is usually provided by a gate driver. Thus, the minimum opening duration of the transistor imposes a limit on how short the laser pulse can be. One solution is to implement a capacitor in line with the transistor. The capacitor is charged and then discharged through the laser. However, a capacitor, by nature, has an exponential discharge curve. Thus, the tail of the discharge can be relatively late as compared to the beginning of the discharge, thereby creating a longer than desired pulse. The use of the capacitor generally results in a pulse that is not much shorter than 1 nanosecond (ns).

In some systems or devices utilizing pulsed light sources, multichannel light sources are used. In these applications it is usually desirable to have the channels being able to work independently from other channels. Specifically, some channels may need to be lit up simultaneously while other channels need to stay off during the pulse. Additionally, some channels that are lit during a pulse may need to be lit with different pulse intensities and durations from other channels that are also lit during the same pulse. Conventional triggering solutions require fast-switching power transistors for every channel resulting in bulky and expensive circuitry. Additionally, synchronizing the pulses across channels becomes a challenge and generally requires synchronization circuits that are expensive and complex. These conventional solutions also increase a parasitic inductance which degrades the overall performance of a system.

Further, in traditional laser switching circuits for multichannel lasers, every laser channel has to be operated by a dedicated fast-switching power transistor, and the gates of those transistors are driven by dedicated gate drivers. In an instance when multiple channels are to be simultaneously fired, synchronization of the pulses becomes a problem because ensuring that the same signal delay across multiple traces from signal generator to gate drivers and then to the gates becomes challenging. Additionally, the inductance of signal traces from lasers through transistors to the ground can be hard to minimize, especially if the multichannel laser package is smaller than the packages of all the transistors combined. The additional inductance deteriorates the pulse or the rise time of the pulses.

Accordingly, a laser diode switching circuit, for example, those used in a LiDAR system or other electronic system or device utilizing pulsed light sources, may include use of a semiconductor opening switch (SOS) which utilizes a reverse recovery effect of the diode or junction to terminate the current. Reverse recovery is an inherent feature of some semiconductor structures, for example, semiconductor diodes, that is generally considered to be parasitic and, therefore, undesirable. Generally, the reverse recovery effect is a source of inefficiency in electronic circuits, for example, in rectifiers, switching power supplies, and the like.

The reverse recovery effect is generated when the semiconductor structure, for example, the diode is switched from one bias mode to another. For example, when the laser diode switching circuit is positively biased, a diode may store electrons in its p-conductive region and holes may be present in its n-conductive region. These electrons and holes are known as non-equilibrium charge carriers. Then, when the diode is switched quickly into a reverse bias from the positive bias, the generation of non-equilibrium charge carriers may stop abruptly. However, the existing non-equilibrium charge carriers do not dissipate immediately and may continue to conduct in the reverse bias for a short time, thereby creating the reverse recovery effect. The length of time of the reverse recovery effect may depend on a value of the reverse voltage applied to the diode and may rely on a value of forward current before switching.

The reverse recovery effect can be used to terminate the current through the laser. The biggest problem in conventional systems with getting a short pulse through the laser is that the transistor switching circuit does not switch that quickly. Accordingly, by utilizing the reverse recovery effect, the current through the laser can be terminated before the transistor is able to be switched off, thereby shortening the current pulse through the laser and in turn shortening the laser pulse without having to rely on the transistor to close. Thus, the use of the reverse recovery effect shortens the pulse time as compared to conventional systems that rely on the transistor switching time.

The reverse recovery effect is present in many semiconductor structures that may contain at least one p-n junction or Schottky barrier. Accordingly, different devices may be used as the semiconductor opening switches (SOS) utilized in the system described herein. Some example components that may be used as SOS may include p-n, p-i-n, and Schottky diodes, dinistors, thyristors, triacs, silicon-controlled rectifiers (SCRs), Shockley diodes, transistors, and the like. It should be understood that these are merely examples and a non-exhaustive list and any component that includes the reverse recovery effect may be utilized in the described system. For ease of readability, the description will refer to diodes, but this is not intended to limit the scope of this invention in any way. Additionally, the description will refer to laser light sources. However, the described system can be applied to any system or device utilizing pulsed light sources, pulsed circuits or components, or other circuits, devices, or systems that require fast switching. Thus, the use of the term laser is not intended to limit the scope of this disclosure in any way. Additionally, the term light emitting device may be used and includes light emitting diodes, lasers, and other devices or components that emit light in either visible or other wavelengths.

Not only can the SOS switching circuit be used to cut current to the laser, referred to as a cut-off switch, but it can also be used to provide the current to the laser or other switching component, referred to as a cut-on switch. In other words, the SOS can also be used to control the onset of the current pulse through the laser. In this configuration, the forward-biased SOS is connected in parallel with the laser or other switching component. When the transistor switches the circuit on, the SOS acts as a current bypass during its reverse recovery, meaning the current flows through the SOS during its reverse recovery instead of through the laser or other switching component. Using the SOS as a current bypass during the reverse recovery process allows the transistor to be switched on fully during this process. When the reverse recovery process has ended, the SOS stops conducting and the current is routed through the laser or other switching component, increasing the cut-on speed of the laser or other switching component.

The SOS diode-based switching circuit, in either or both the cut-off and/or the cut-on mode, may also be used in multichannel lasers, or other systems or devices that have or use multichannel switching or light sources, to overcome the issues previously mentioned, for example, synchronization problems and inductance deteriorating a pulse rise time. Additionally, the use of the reverse recovery effect in the multichannel systems, reduces the complexity of the circuit and also reduces the number of complex components that need to be utilized as compared to traditional systems.

The system relies on the fact that the SOS diode-based laser switching circuit does not conduct in reverse if forward bias was not applied beforehand. If a forward bias is not applied beforehand then no existing non-equilibrium charge carriers are present. Thus, conducting in the reverse bias does not occur because of the lack of conducting charge carriers present when the bias switches. Thus, by setting forward bias currents through the SOS switches at specific values, when the transistors are opened, the lasers will start generating light pulses simultaneously. It should be noted that the system may include a single transistor that controls all of the laser diodes. There may also be a single transistor that controls more than one laser diode, for example, one transistor may control two or three laser diodes.

However, if the forward bias current for an SOS switch is zero or negative, then that corresponding laser will not produce a light pulse. Thus, the forward bias for the diode can be set ahead of time and when the transistor is opened, the light pulse will be generated if the switch had a positive forward bias. On the other hand, if the switch had no or negative forward bias before the opening of the transistor, the light pulse will remain off. Additionally, since the amount of current through the switch is based upon the forward bias value, the pulse intensity, pulse width, and/or pulse duration for the light pulse can be modified based upon the applied forward bias value.

One advantage to using the SOS diode-based switching circuit is that the channels can be synchronized without expensive synchronization circuitry. For example, using the cut-on mode of the SOS switches, setting forward bias currents through the SOS switches at specific values allows all the lasers to start generating light pulses simultaneously when the transistor of the multichannel configuration is opened. However, if the forward bias current for an SOS is zero or negative, that corresponding laser will not produce a light pulse. Thus, the forward bias for the diodes can be set ahead of time and when the transistors are opened simultaneously the light pulses for those channels having a positive forward bias will be generated simultaneously, while the channels with no or negative forward bias will remain off. Additionally, since the amount of current through the switch is based upon the forward bias value, each channel can have a different pulse intensity, pulse width, and/or pulse duration based upon the applied forward bias value.

Similarly, the cut-off mode can additionally or alternatively be used in the multichannel configuration, thereby allowing for synchronization of the shortening of the pulses through all the channels. Thus, the system allows for independent control of each channel of the multichannel system while still allowing for synchronization of the channels, without requiring complex synchronization circuits and the deteriorating the pulse rise time as found in conventional multichannel systems. Additionally, since the pulse duration is actually controlled by the diode, the transistor employed in this configuration does not have to be a fast-switching transistor, thereby reducing the overall cost of the multichannel system.

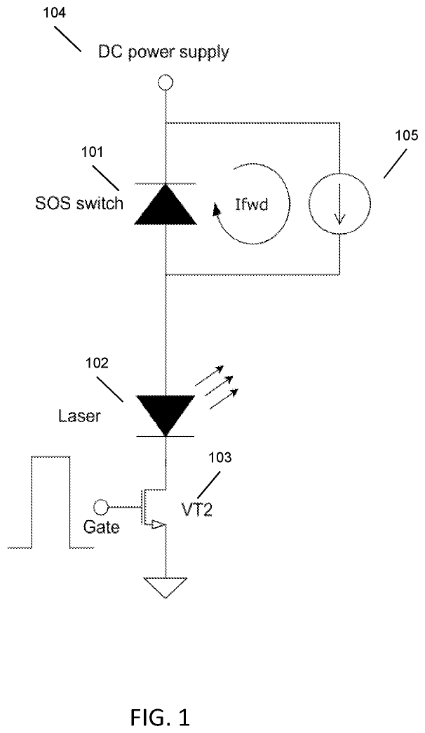

FIG. 1 illustrates an example switching circuit utilizing a semiconductor opening switch 101 to provide electrical current or power to an electrical component 102, in this example case a laser diode. As illustrated in this example circuit, the semiconductor opening switch (SOS) is connected to the input side of the laser diode. Specifically, the SOS is electrically located between the power supply 104 and the laser diode 102, thereby acting as a switch for the laser diode 102. In other words, the SOS controls the electrical current to the laser diode 102. On the output side of the laser diode 102 is a transistor 103.

The electrical connection between the laser diode 102 and the transistor 103 is similar to what is found in conventional systems. In the conventional systems, the transistor 103 acts to control the electrical current to the transistor. In the described system utilizing the SOS, however, the SOS works with the transistor to control the electrical current to the laser diode. When the transistor is off, a dedicated current source 105 generates a small forward standby current (Ifwd) through the SOS allowing the SOS to remain in a positively biased state, also referred to as forward biased. Generally, the standby current Ifwd is kept small in comparison to the peak operating current. While positively biased, the SOS stores electrons in its p-conductive region and holes in its n-conductive region. These electrons and holes are called non-equilibrium charge carriers.

When the transistor is switched on, a reverse current is applied to the SOS, thereby transitioning the SOS to a negative bias, also referred to as reverse bias, and entering the reverse recovery state. During the reverse recovery state, the SOS no longer generates new non-equilibrium charge carriers. However, the existing non-equilibrium charge carriers do not dissipate immediately, thereby allowing the SOS to conduct in reverse until all the non-equilibrium charge carriers are depleted. Once all the non-equilibrium charge carriers are depleted, the SOS abruptly stops conducting, thereby cutting off the current through the laser diode so the diode stops emitting light. Since the SOS abruptly stops conducting upon depletion of the non-equilibrium charge carriers, the cut off in such a system is sharper than systems utilizing capacitors. In the described switching circuit, the parameters of components may be picked such that the laser pulse duration does not depend on a gate pulse width or a transition opening time, but may solely be based on the amount of non-equilibrium charge carriers stored in the SOS before the transistor is switched on. Accordingly, the duration of the reverse recovery state and, therefore, the electrical pulse provided to the laser diode, is based upon a value of the forward current provided during the forward bias state and a value of the reverse voltage provided during the reverse bias state.

Thus, the electrical pulse duration is not based upon the transistor switching time, but rather relies on the SOS. Accordingly, the duration of the pulse to the laser may be less than the transistor switching duration. This allows for a much shorter current pulse being provided to the laser diode than in the conventional systems that rely on the transistor switching duration. Additionally, since the system no longer relies on the transistor switching duration, the system can utilize transistors other than fast-switching transistors, thereby reducing the cost of the overall system.

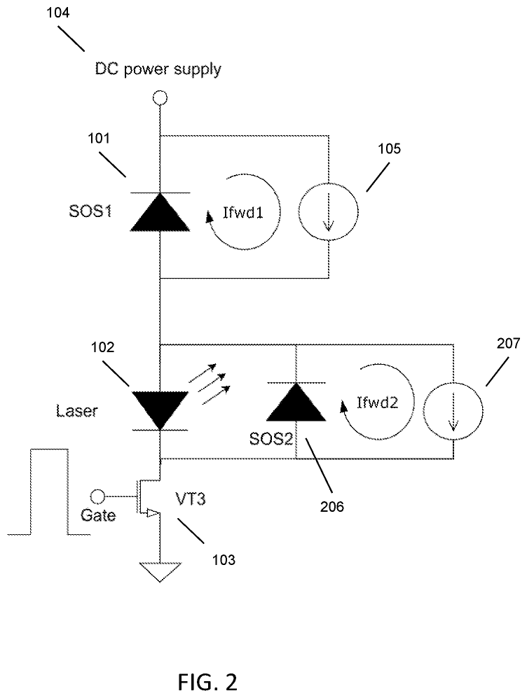

Not only can the SOS be utilized for cutting off current through the laser diode, but it may also be used to start the laser pulse. FIG. 2 illustrates an example that utilizes an SOS for cut-on for the laser. For ease of understanding, the components illustrated in FIG. 1 describing the cut-off SOS are duplicated in FIG. 2. The reference numbers are also maintained for clarity. FIG. 2 adds the additional components for the cut-on SOS. As illustrated in FIG. 2 in addition to providing an SOS in series with the laser diode, which provides the cut-off for the laser diode (described in connection with FIG. 1), an SOS 206 is provided in parallel with the laser, which provides the cut-on for the laser diode. This diode configuration is referred to as a shunt diode. As with the cut-off SOS 101, the cut-on SOS 206 is provided with a dedicated current source 207.

It should be understood that the cut-off portion of the illustrated example works in the same manner as that described in connection with FIG. 1. Thus, this description will not be reiterated here. Instead, the description of FIG. 2 will focus on the workings of the cut-on portion of the illustrated example with the understanding that the remaining portion of the circuit will work as described in connection with FIG. 1. When the transistor (VT3 in FIG. 2) 103 is turned off, the dedicated current source 207 generates a standby forward current (Ifwd2) through the SOS2 206. When the transistor 103 opens, the laser remains off because both SOS's 101 and 206 enter recovery mode, also referred to as the reverse recovery state, which results in current flowing from the DC power source 104 to ground through SOS2 206 but not through the laser 102.

The circuit may be configured such that SOS2 206 stores less non-equilibrium carriers than SOS1 101. Therefore, SOS2 206 closes first and re-routes the current through the laser 102. As with the cut-off circuit, the onset of the current pulse through the laser no longer depends on the opening speed of the transistor 103, for the same reasons as discussed in connection with the cut-off circuit described in FIG. 1. It should be understood that the examples illustrated in the figures are not meant to narrow the disclosure to these specific configurations. Rather, other configurations using a cut-off switch, a cut-on switch, a plurality of either or both cut-off and/or cut-on switches, or the like, may be used. For example, since SOS2 206 closes later than SOS1 101, thereby cutting off the laser current, the circuit could simply utilize SOS2 206 (cut-on switch) without the use of SOS1 101 (cut-off switch). As another example, it is possible to utilize a single standby current source for both SOS1 and SOS2. In this case, SOS2 may be constructed to store less non-equilibrium charge carriers than SOS1 at the same standby forward current.

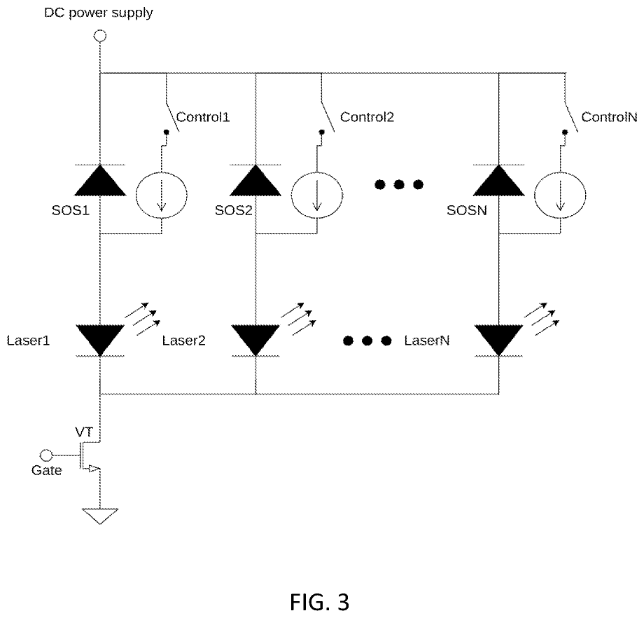

Further, instead of a single cut-off and/or cut-on switch configuration, also referred to as a single channel system, the described system may be utilized in a multichannel system, as illustrated in FIG. 3. As mentioned previously, issues regarding synchronization and high inductance are present when utilizing a laser switching circuit for multichannel lasers in conventional systems. The described system utilizing the SOS diode-based laser switching circuit solves many of these problems. The multichannel configuration relies on the fact that the SOS may not conduct in reverse if forward bias was not applied beforehand. In other words, if no forward current was applied to an SOS, application of reverse bias does not result in current flow through an SOS.

FIG. 3 illustrates a multichannel system where the configuration illustrated in FIG. 1 is illustrated in a multichannel configuration having each SOS circuit in parallel with the other SOS circuits. In an embodiment, when a transistor (VT in FIG. 3) is turned off, the regulator switches (Control1, Control2, ControlN) may be used to set the forward bias current through the SOSs (SOS1, SOS2, SOSN, respectively) to desired values which may include zero or negative values. If the forward bias current is set to zero or negative values, the corresponding SOSs will not conduct current upon the transistor opening or turning on. Since, the forward bias current can be set independently for each SOS, each channel, and, therefore, each laser diode can have different pulse intensities and/or pulse durations.

Since a single transistor is used for all or a plurality of the channels, upon opening the transistor, a reverse current is applied to all of the SOSes electrically connected to the transistor at the same time or simultaneously, thereby synchronizing all the channels corresponding to the transistor. Thus, a complicated synchronization circuit, as required in conventional solutions, is not required in such a multichannel system. However, the duration, width, and/or intensity of the light pulses may be different depending on the initial forward current values though the respective SOS switches. Additionally, the lasers in series with each SOS that had zero or negative forward bias may not produce light at all.

Accordingly, in the described system, the systems that provide forward bias current to the SOSes do not require high frequency tracing, and may be implemented as affordable low-current low-speed transistors, which may decrease the cost as compared to a traditional circuit. Additionally, the inductance of the traces between the SOS and corresponding laser diode are easier to keep to a minimum as compared to a traditional system, especially if the SOSes are implemented in the same or similar size package as the multichannel laser. Additionally, in an embodiment, the same package may contain multichannel lasers, SOS diodes, forward current sources, control multiplexer, and a logic circuit that may determine which lasers have to be switched to which duration during the next laser pulse, thereby decreasing the need for complex and/or expensive circuitry as compared to traditional techniques. It may also be possible to control the onset of laser pulses in a multichannel configuration using SOS cut-on switches in a manner similar to that as described in connection with FIG. 2.

Example embodiments are described herein with reference to the figures, which illustrate example methods, devices and program products according to various example embodiments. It will be understood that the actions and functionality may be implemented at least in part by program instructions. These program instructions may be provided to a processor of a device, a special purpose information handling device, or other programmable data processing device to produce a machine, such that the instructions, which execute via a processor of the device implement the functions/acts specified.

It is worth noting that while specific blocks are used in the figures, and a particular ordering of blocks has been illustrated, these are non-limiting examples. In certain contexts, two or more blocks may be combined, a block may be split into two or more blocks, or certain blocks may be re-ordered or re-organized as appropriate, as the explicit illustrated examples are used only for descriptive purposes and are not to be construed as limiting.

As used herein, the singular “a” and “an” may be construed as including the plural “one or more” unless clearly indicated otherwise.

This disclosure has been presented for purposes of illustration and description but is not intended to be exhaustive or limiting. Many modifications and variations will be apparent to those of ordinary skill in the art. The example embodiments were chosen and described in order to explain principles and practical application, and to enable others of ordinary skill in the art to understand the disclosure for various embodiments with various modifications as are suited to the particular use contemplated.

Thus, although illustrative example embodiments have been described herein with reference to the accompanying figures, it is to be understood that this description is not limiting and that various other changes and modifications may be affected therein by one skilled in the art without departing from the scope or spirit of the disclosure.

What is claimed is:

1. A method for providing a short electrical pulse using a switching circuit, the method comprising:
providing a forward current to at least one semiconductor diode electrically connected with and controlling electrical current to an electrical component within a circuit; and
switching the at least one semiconductor diode into a reverse bias by applying a reverse voltage to the at least one semiconductor diode, thereby causing the at least one semiconductor diode to enter a reverse recovery state and controlling a destination of the electrical current and generating the short electrical pulse to the destination for the duration of the reverse recovery state;
the duration of the reverse recovery state being based upon a value of the forward current and a value of the reverse voltage.

2. The method of claim 1, wherein the at least one semiconductor diode is electrically in-line with the electrical component;
wherein, during the reverse recovery state, the destination of the electrical current is the electrical component and is provided from the at least one semiconductor diode; and
wherein the duration of the electrical current provided to the electrical component is equal to the duration of the reverse recovery state, thereby providing the short electrical pulse to the electrical component.

3. The method of claim 1, wherein the at least one semiconductor diode is electrically in parallel with the electrical component;
wherein, during the reverse recovery state, the destination of the electrical current is ground, the at least one semiconductor diode acting as a bypass for the electrical current during the reverse recovery state; and
wherein, upon termination of the reverse recovery state, the electrical current flows through the electrical component.

4. The method of claim 1, wherein the forward current is provided while a transistor electrically connected to the electrical component is switched off; and
wherein the reverse voltage is provided while the transistor is switched on.

5. The method of claim 1, further comprising controlling at least one of a pulse intensity, pulse width, and pulse duration by adjusting the value of the forward current.

6. The method of claim 1, wherein the at least one semiconductor diode comprises a plurality of semiconductor diodes;
wherein the electrical component comprises a multichannel electrical component; and
wherein each of the plurality of semiconductor diodes is connected in series to and controls at least one channel of the multichannel electrical component.

7. The method of claim 6, wherein the value of the forward current for each of the plurality of semiconductor diodes is set independently from other of the plurality of semiconductor diodes.

8. The method of claim 6, wherein the number of semiconductor diodes is fewer than the total number of channels in all multichannel electrical components combined.

9. The method of claim 1, wherein the providing a forward current is performed by a dedicated current source.

10. The method of claim 1, wherein the electrical component comprises a light emitting device.

11. A device for providing a short electrical pulse using a switching circuit, the device comprising:
an electrical component receiving an electrical current; and
at least one semiconductor diode electrically connected with the electrical component, wherein the at least one semiconductor diode controls electrical current to the electrical component and wherein control of the at least one semiconductor diode controls a duration of the electrical current;
wherein the control of the at least one semiconductor diode comprises providing a forward current to at least one semiconductor diode electrically connected with and controlling electrical current to an electrical component within a circuit and switching the at least one semiconductor diode into a reverse bias by applying a reverse voltage to the at least one semiconductor diode, thereby causing the at least one semiconductor diode to enter a reverse recovery state and controlling a destination of the electrical current and generating the short electrical pulse to the destination for the duration of the reverse recovery state;
the duration of the reverse recovery state being based upon a value of the forward current and a value of a reverse voltage applied during the reverse bias.

12. The device of claim 11, wherein the at least one semiconductor diode is electrically in-line with the electrical component;
wherein, during the reverse recovery state, the destination of the electrical current is the electrical component and is provided from the at least one semiconductor diode; and
wherein the duration of the electrical current provided to the electrical component is equal to the duration of the reverse recovery state, thereby providing the short electrical pulse to the electrical component.

13. The device of claim 11, wherein the at least one semiconductor diode is electrically in parallel with the electrical component;
wherein, during the reverse recovery state, the destination of the electrical current is ground, the at least one semiconductor diode acting as a bypass for the electrical current during the reverse recovery state; and
wherein, upon termination of the reverse recovery state, the electrical current flows through the electrical component.

14. The device of claim 11, further comprising a transistor electrically connected to the electrical component;
wherein the forward current is provided while the transistor is switched off; and
wherein the reverse voltage is provided while the transistor is switched on.

15. The device of claim 11, wherein the control further comprises controlling at least one of a pulse intensity, pulse width, and pulse duration by adjusting the value of the forward current.

16. The device of claim 11, wherein the at least one semiconductor diode comprises a plurality of semiconductor diodes;
wherein the electrical component comprises a multichannel electrical component; and
wherein each of the plurality of semiconductor diodes is connected in series to and controls at least one channel of the multichannel electrical component.

17. The device of claim 16, wherein the value of the forward current for each of the plurality of semiconductor diodes is set independently from other of the plurality of semiconductor diodes.

18. The device of claim 16, wherein the number of semiconductor diodes is fewer than the total number of channels in all multichannel electrical components combined.

19. The device of claim 11, wherein the providing a forward current is performed by a dedicated current source.

20. The device of claim 11, wherein the electrical component comprises a light emitting device.
